(19) United States
(12) Patent Application Publication
(10) Pub. No.: US 2026/0059973 A1
(43) Pub. Date: Feb. 26, 2026

(54) TRANSPARENT DISPLAY APPARATUS

(71) Applicant: LG Display Co., Ltd., Seoul (KR)

(72) Inventor: Hoiyong KWON, Paju-si (KR)

(73) Assignee: LG Display Co., Ltd., Seoul (KR)

(21) Appl. No.: 19/276,831

(22) Filed: Jul. 22, 2025

(30) Foreign Application Priority Data
Aug. 22, 2024 (KR) 10-2024-0113082

(51) Int. Cl. H10K 59/80; H10K 59/122; H10K 59/131; H10K 59/38

(52) U.S. Cl. CPC H10K 59/8723; H10K 59/122; H10K 59/131; H10K 59/38; H10K 59/873; H10K 59/8792

(57) ABSTRACT

A transparent display apparatus in some examples can include a substrate having a plurality of pixels each having a transmissive area and a plurality of subpixels, an auxiliary line arranged on the substrate and overlapping the transmissive area, a planarization layer arranged on the auxiliary line, a blocking portion arranged between the planarization layer and the auxiliary line, a plurality of undercut portions partially arranged on an upper side and a lower side of the blocking portion, an opposing substrate arranged on the planarization layer, and a plurality of spacers arranged between the planarization layer and the opposing substrate.

### CROSS-REFERENCE TO RELATED APPLICATIONS

This application claims priority to Korean Patent Application No. 10-2024-0113082, filed in the Republic of Korea on Aug. 22, 2024, the entire contents of which are hereby expressly incorporated by reference as if fully set forth herein into the present application.

### BACKGROUND

### Technical Field

The present disclosure relates to a transparent display apparatus.

### Discussion of the Related Art

With the advancement of the information age, the demand for a display apparatus for displaying an image has increased in various forms. Recently, studies for a transparent display apparatus in which a user can view objects or background positioned at an opposite side by transmitting the display apparatus are actively ongoing.

The transparent display apparatus can include a display area, on which an image is displayed, in a display panel, and the display area can include a transmissive area capable of transmitting external light and a non-transmissive area that does not transmit light. The non-transmissive area can include a plurality of light emission areas having a light-emitting element that emit light.

These transparent display apparatuses mainly adopt a top emission method in which light is emitted upward, and can be configured by bonding a lower substrate (or array substrate) on which a plurality of pixels that emit light to display an image are arranged, and an upper substrate (or color filter substrate) on which a plurality of color filters corresponding to each of the plurality of pixel are arranged. However, in transparent display apparatuses, foreign substances can be generated due to the collapse of a cell gap between the lower substrate and upper substrate or sagging of the substrates, and the foreign substances can cause pixel defects. Therefore, it is needed to maintain the cell gap between the lower substrate and upper substrate.

### SUMMARY OF THE DISCLOSURE

An aspect of the present disclosure is directed to providing a transparent display apparatus in which a cell gap between a substrate (e.g., a lower substrate) and an opposing substrate (e.g., an upper substrate) can be maintained.

Further, an aspect of the present disclosure is directed to providing a transparent display apparatus capable of blocking, preventing, or minimizing crack propagation through an encapsulation layer.

Further, an aspect of the present disclosure is directed to providing a transparent display apparatus capable of preventing or minimizing moisture penetration into a light-emitting element.

Further, an aspect of the present disclosure is directed to providing a transparent display apparatus that can be driven with low power compared to the entire lifespan due to the improved lifespan of the light-emitting element, thereby reducing power consumption.

Further, an aspect of the present disclosure is directed to providing a transparent display apparatus in which the reduction in transmittance (or transparency) can be minimized.

Further, an aspect of the present disclosure is directed to providing a transparent display apparatus capable of improving reliability against external force.

The problems to be solved or addressed by the examples of the present disclosure are not limited to those mentioned above, and other problems and limitations not mentioned will be apparent to one of ordinary skill in the art to which the technical spirits of the present disclosure belong from the following description.

A transparent display apparatus according to one or more embodiments of the present disclosure can include a substrate having a plurality of pixels each having a transmissive area and a plurality of subpixels, an auxiliary line arranged on the substrate and overlapping the transmissive area, a planarization layer arranged on the auxiliary line, a blocking portion arranged between the planarization layer and the auxiliary line, a plurality of undercut portions partially arranged on upper side and lower side of the blocking portion, an opposing substrate arranged on the planarization layer, and a plurality of spacers arranged between the planarization layer and the opposing substrate.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a schematic plan view of a transparent display apparatus according to one or more embodiments of the present disclosure.

FIG. 2 is a schematic enlargement of portion A of FIG. 1, showing a plurality of pixels.

FIG. 3 is a schematic cross-sectional view of the line I-I′ shown in FIG. 2.

FIG. 4 is a schematic enlargement of portion B of FIG. 3.

FIG. 5 is a schematic cross-sectional view showing another example of a color filter illustrated in FIG. 3.

FIG. 6 is a plan view showing a transparent display apparatus according to another embodiment of the present disclosure.

FIG. 7 is a schematic enlargement view of portion C of FIG. 6.

### DETAILED DESCRIPTION OF THE EMBODIMENTS

Reference will now be made in detail to the embodiments of the present disclosure, examples of which are illustrated in the accompanying drawings. Wherever possible, the same reference numbers will be used throughout the drawings to refer to the same or like parts. Advantages and features of the present disclosure, and implementation methods thereof will be clarified through following embodiments described with reference to the accompanying drawings.

The present disclosure may, however, be embodied in different forms and should not be construed as limited to the embodiments set forth herein.

Rather, these embodiments are provided so that this disclosure will be thorough and complete, and will fully convey the scope of the present disclosure to those skilled in the art.

A shape, a size, a ratio, an angle, and a number disclosed in the drawings for describing embodiments of the present disclosure are merely one example, and thus, the present disclosure is not limited to the illustrated details. Like reference numerals refer to like elements throughout.

In the following description, when the detailed description of the relevant known function or configuration is determined to unnecessarily obscure the important point of the present disclosure, the detailed description will be omitted.

In a case where ‘comprise’, ‘have’, and ‘include’ described in the present disclosure are used, another part can be added unless ‘only’ is used. The terms of a singular form can include plural forms unless referred to the contrary.

In construing an element, the element is construed as including an error range although there is no explicit description.

In describing a position relationship, for example, when a position relation between two parts is described as ‘on’, ‘over’, ‘under’, and ‘next’, one or more other parts can be disposed between the two parts unless ‘just’ or ‘direct’ is used.

In describing a temporal relationship, for example, when the temporal order is described as “after,” “subsequent,” “next,” and “before,” a case which is not continuous can be included, unless “just” or “direct” is used.

It will be understood that, although the terms “first,” “second,” etc. can be used herein to describe various elements, these elements should not be limited by these terms. These terms are only used to distinguish one element from another and may not define order or sequence. For example, a first element could be termed a second element, and, similarly, a second element could be termed a first element, without departing from the scope of the present disclosure.

Further, “X-axis direction”, “Y-axis direction” and “Z-axis direction” should not be construed by a geometric relation only of a mutual vertical relation and can have broader directionality within the range that elements of the present disclosure can act functionally.

The term “at least one” should be understood as including any and all combinations of one or more of the associated listed items. For example, the meaning of “at least one of a first item, a second item and a third item” denotes the combination of all items proposed from two or more of the first item, the second item and the third item as well as the first item, the second item or the third item. Also, the term “can” fully encompasses all the meanings and coverages of the term “may” and vice versa.

Features of various embodiments of the present disclosure can be partially or overall coupled to or combined with each other and can be variously inter-operated with each other and driven technically as those skilled in the art can sufficiently understand.

The embodiments of the present disclosure can be carried out independently from each other or can be carried out together in co-dependent relationship.

Hereinafter, the various embodiments of the present disclosure will be described in detail with reference to the accompanying drawings. All the components of each display apparatus according to all embodiments of the present disclosure are operatively coupled and configured.

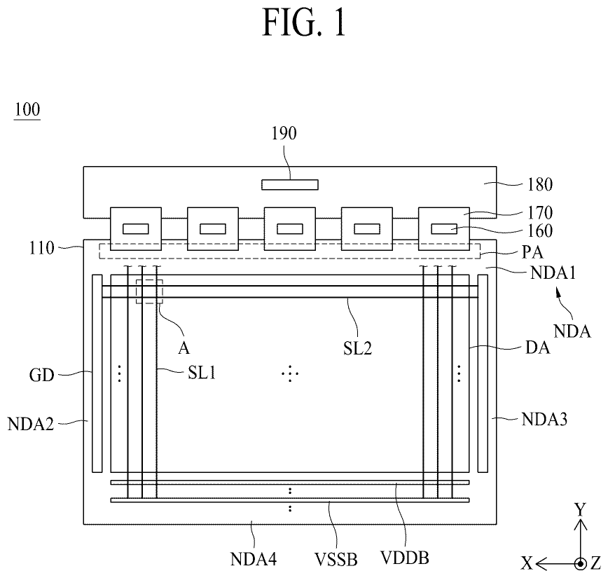

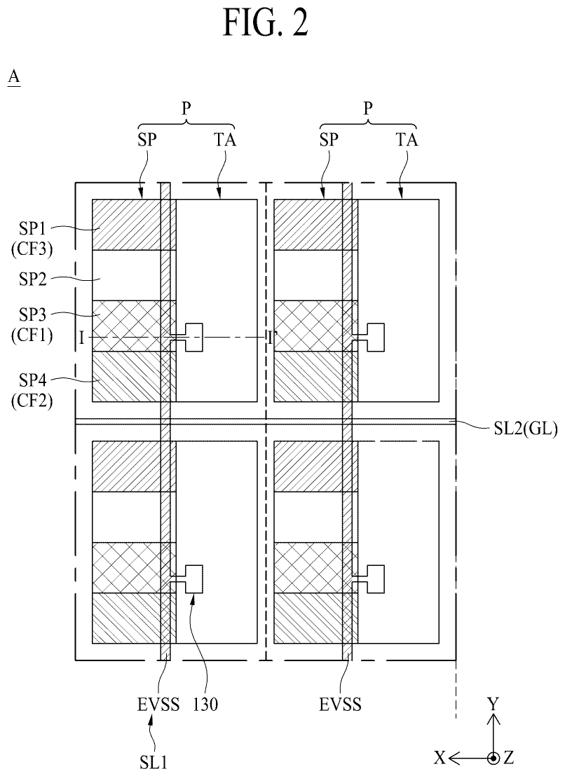

FIG. 1 is a schematic plan view of a transparent display apparatus according to one or more embodiments of the present disclosure, and FIG. 2 is a schematic enlargement of portion A of FIG. 1, showing a plurality of pixels.

Hereinafter, a first direction (e.g., Y-axis direction) represents a direction parallel to the common power line EVSS (or data line), a second direction (e.g., X-axis direction) represents a direction parallel to the gate line GL, and a third direction (e.g., Z-axis direction) represents a thickness direction of the transparent display apparatus 100.

The following description will be based on that a transparent display apparatus 100 according to one or more embodiments of the present disclosure is an organic light emitting display apparatus, but is not limited thereto. For example, the transparent display apparatus according to one or more embodiments of the present disclosure can be implemented as any one of a liquid crystal display apparatus, a field emission display apparatus, a quantum dot (QD) lighting emitting diode apparatus, and an electrophoretic display apparatus as well as the organic light emitting display apparatus.

Referring to FIGS. 1 and 2, the transparent display apparatus 100 according to one or more embodiments of the present disclosure can include a display panel having a gate driver GD, a source drive integrated circuit (hereinafter, referred to as “IC”) 160, a flexible film 170, a circuit board 180, and a timing controller 190.

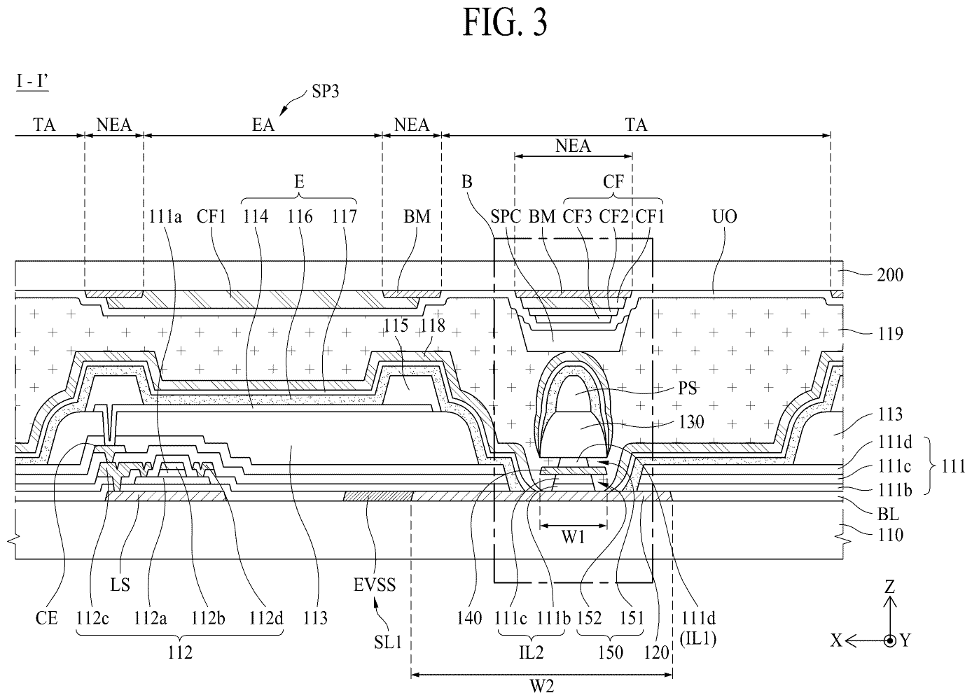

The display panel can include a substrate 110 and an opposing substrate 200 (shown in FIG. 3) bonded to each other. The substrate 110 can include an auxiliary line 120, a planarization layer 130, a blocking portion 140, and a plurality of undercut portions 150. Since the substrate 110 is bonded to the opposing substrate 200, the opposing substrate 200 can be placed on the planarization layer 130. A plurality of spacers SPC can be placed between the planarization layer 130 and the opposing substrate 200.

In the case of a general transparent display apparatus, foreign matter can be generated due to the collapse of the cell gap between a lower substrate and an upper substrate or sagging of the substrate. Therefore, in the case of a general transparent display apparatus, pixel defects can occur due to foreign substance.

In contrast, the transparent display apparatus 100 according to one embodiment of the present disclosure has the plurality of spacers SPC provided between the substrate 110 (or the planarization layer 130) and the opposing substrate 200, so that the cell gap between the substrate 110 and the opposing substrate 200 does not collapse or the substrate sag does not occur, and therefore foreign substance may not be generated. Therefore, the transparent display apparatus 100 according to one embodiment of the present disclosure can prevent pixel defects caused by foreign substance resulting from the cell gap defects or the substrate sagging.

The substrate 110 can include a thin film transistor, and can be a transistor array substrate, a lower substrate, a base substrate, or a first substrate. The substrate 110 can be a transparent glass substrate or a transparent plastic substrate.

The opposing substrate 200 can be bonded to the substrate 110 via an adhesive member. For example, the opposing substrate 200 can have a size smaller than that of the substrate 110, and can be bonded to the remaining portion except the pad area of the substrate 110. The opposing substrate 200 can be an upper substrate, a second substrate, or an encapsulation substrate.

The gate driver GD supplies gate signals to the gate lines in accordance with the gate control signal input from the timing controller 190. When the source drive IC 160 is manufactured as a driving chip, the source drive IC 160 can be packaged in the flexible film 170 in a chip on film (COF) method or a chip on plastic (COP) method.

Pads such as power pads and data pads can be formed in a non-display area of a display panel. A flexible film 170 can include lines connecting the pads to a source drive IC 160 and lines connecting the pads to lines of a circuit board 180. The flexible film 170 can be attached to the pads by using an anisotropic conducting film, whereby the pads can be connected to the lines of the flexible film 170.

The substrate 110 according to one example can include a display area DA and a non-display area NDA. The non-display area NDA can surround the display area DA entirely or only in part(s).

The display area DA is an area where an image is displayed, and can be a pixel array area, an active area, a pixel array unit, a display unit, or a screen. For example, the display area DA can be disposed at a central portion of the display panel.

The display area DA according to one example can include gate lines, data lines, pixel driving power lines, and a plurality of pixels P (shown in FIG. 2). Each of the plurality of pixels P can include a plurality of sub-pixels SP that can be defined by the gate lines and the data lines, and a transmissive area TA positioned adjacent to some or all of the plurality of subpixels SP. The transmissive area TA is an area provided to allow light to transmit front and rear surfaces of the display panel. Therefore, a user located in the direction of the front surface of the display panel can view a backgrounds or an images positioned in the direction of the rear surface of the display panel through the transmissive area TA.

Each of the plurality of sub-pixels SP can be defined as a minimum unit area in which light is actually emitted.

According to one example, at least four sub-pixels, which are provided to emit light of different colors and disposed to be adjacent to one another, among the plurality of sub-pixels SP, and one transmissive area TA constitute one unit pixel P. One transmissive area TA included in the unit pixel can be disposed to be divided into a plurality of parts. One unit pixel can include, but is not limited to, a red sub-pixel, a white sub-pixel, a blue sub-pixel, a green sub-pixel and a transmissive area TA. According to another example, three sub-pixels SP, which are provided to emit light of different colors and disposed to be adjacent to one another, among the plurality of sub-pixels SP, and one transmissive area TA constitute one unit pixel. One unit pixel can include at least one red sub-pixel, at least one green sub-pixel, at least one blue sub-pixel and one transmissive area TA, but is not limited thereto.

Each of the plurality of sub-pixels SP can include a thin film transistor and a light emitting element connected to the thin film transistor. The sub-pixel can include a light emitting layer (or an organic light emitting layer) interposed between a first electrode and a second electrode.

The light emitting layer disposed in each of the plurality of sub-pixels SP can individually emit light of different colors, or can commonly emit white light. According to one example, when the light emitting layer of each of the plurality of sub-pixels SP commonly emits white light, each of the red sub-pixel, the green sub-pixel and the blue sub-pixel can include a color filter (or a wavelength conversion member) for converting the white light into light of different colors. In this case, the white sub-pixel according to one example may not include a color filter. The color filter CF, according to one example, can include a blue color filter CF1, a green color filter CF2, and a red color filter CF3.

In the transparent display apparatus 100 according to one embodiment of the present disclosure, an area in which a red color filter CF3 is provided can be a red sub-pixel SP1, an area in which a blue color filter CF1 is provided can be a blue sub-pixel SP3, an area in which a green color filter CF2 is provided can be a green sub-pixel SP4, and an area in which a color filter is not provided can be a white sub-pixel SP2. In the present disclosure, the red sub-pixel SP1 can be expressed as a first sub-pixel provided to emit red light, the blue sub-pixel SP3 can be represented as a third sub-pixel provided to emit blue light, the green sub-pixel SP4 can be expressed as a fourth sub-pixel provided to emit green light, and the white sub-pixel SP2 can be represented as a second sub-pixel provided to emit white light.

Each of the plurality of sub-pixels SP supplies a predetermined current to the organic light emitting element in accordance with a data voltage of the data line when a gate signal is input from the gate line by using the thin film transistor. For this reason, the light emitting layer of each of the sub-pixels can emit light with a predetermined luminance in accordance with the predetermined current.

Referring to FIG. 2, the display area DA includes a transmissive area TA and a non-transmissive area. The transmissive area TA is an area through which most of light incident from the outside passes. The non-transmissive area is an area that does not transmit most of light incident from the outside. The non-transmissive area can include a light emission area EA (shown in FIG. 3) and a non-light emission area NEA (shown in FIG. 3). The non-light emission area NEA can be an area other than the light emission area EA from which light is emitted. In one example, the non-light emission area NEA can be provided on the substrate 110 between the transmissive area TA and the plurality of sub-pixels SP (or the plurality of light emission area EA), and between the plurality of sub-pixels SP (or the plurality of light emission area EA).

The plurality of pixels P and a plurality of lines for driving each of the plurality of pixels P can be arranged in the non-light emission area NEA and/or the light emission area EA. The plurality of lines, according to one example, can include a plurality of first signal lines SL1 and a plurality of second signal lines SL2.

The plurality of first signal lines SL1 can be extended in the first direction (Y-axis direction). The plurality of first signal lines SL1 can intersect with a plurality of second signal lines SL2. Each of the plurality of first signal lines SL1 can include a pixel power line and a common power line EVSS arranged separately from the pixel power line. In one example, the common power line EVSS can partially overlap with each of the plurality of subpixels SP. For example, as shown in FIG. 2, the common power line EVSS can be arranged long in the first direction (Y-axis direction) and overlap each of the first to fourth sub-pixels SP1, SP2, SP3, SP4 arranged in the first direction (Y-axis direction).

In one embodiment, the plurality of first signal lines SL1 can further include a plurality of data lines and a reference line. The plurality of data lines can include a first data line for driving a first sub-pixel SP1, a second data line for driving a second sub-pixel SP2, a third data line for driving a third sub-pixel, and a fourth data line for driving a fourth sub-pixel SP4.

Hereinafter, when the first signal line SL1 includes a plurality of lines, one first signal line SL1 can refer to a signal line group comprised of a plurality of lines. For example, when the first signal line SL1 includes four data lines, a pixel power line, a common power line, a reference line, one first signal line SL1 can refer to a signal line group comprised of four data lines, the pixel power line, the common power line, the reference line.

The plurality of second signal lines SL2 can extend in the second direction (X-axis direction). Each of the plurality of second signal lines SL2 can include at least one gate line GL (or scan line GL).

Hereinafter, when the second signal line SL2 includes a plurality of lines, one second signal line SL2 can refer to a signal line group comprised of a plurality of lines. For example, when the second signal line SL2 includes two scan lines GL, one second signal line SL2 can refer to a signal line group comprised of two scan lines.

At least one transmissive area TA can be disposed between the second signal lines SL2 adjacent to each other. In addition, at least one transmissive area TA can be disposed between the first signal lines SL1 adjacent to each other. For example, the transmissive area TA can be surrounded by two first signal lines SL1 and two second signal lines SL2. However, it is not limited to this, and the number of signal lines surrounding the transmissive area TA can change depending on the line layout structure.

Referring back to FIG. 1, the non-display area NDA is an area on which an image is not displayed, and can be a peripheral circuit area, a signal supply area, an inactive area or a bezel area. The non-display area NDA can be configured to be in the vicinity of the display area DA. For example, the non-display area NDA can be disposed to surround the display area DA.

The transparent display apparatus 100 according to one embodiment of the present disclosure can include a pad portion PA disposed in the non-display area NDA. The pad portion PA can be for driving the plurality of pixels P. For example, the pad portion PA can supply power and/or signals for the plurality of pixels P disposed in the display area DA to output images. The non-display area NDA can include a first non-display area NDA1, a second non-display area NDA2, a third non-display area NDA3, and a fourth non-display area NDA4. The pad portion PA according to one example can be disposed in the first non-display area NDA1.

The gate driver GD supplies gate signals to the gate lines in accordance with the gate control signal input from the timing controller 190. The gate driver GD can be formed on one side of the display area DA of the display panel or on the non-display area NDA outside both sides of the display area DA in a gate driver in panel (GIP) method as shown in FIG. 1. Alternatively, the gate driver GD can be manufactured as a driving chip, packaged in a flexible film and attached to the non-display area NDA outside one side or both sides of the display area DA of the display panel by a tape automated bonding (TAB) method.

The plurality of gate drivers GD can be separately disposed on a left side of the display area DA, for example, the second non-display area NDA2 and a right side of the display area DA, for example, the third non-display area NDA3. According to one example, the plurality of gate drivers GD can be connected to the plurality of pixels P and the plurality of second signal lines SL2 for supplying signals to the plurality of pixels P. The plurality of second signal lines SL2 can include at least one signal line for supplying a signal for driving the pixel P.

The plurality of first signal lines SL1 can be extended in the first direction (Y-axis direction). The plurality of first signal lines SL1 can cross the plurality of second signal lines SL2. The plurality of first signal lines can include a pixel power line and at least one data line to supply a data voltage to the pixel P. Each of the plurality of first signal lines SL1 can be connected to at least one of a plurality of pads, a pixel power shorting bar VDDB or a common power shorting bar VSSB. The pixel power shorting bar VDDB and the common power shorting bar VSSB can be disposed in the fourth non-display area NDA4 that is disposed to face the pad area PA based on the display area DA.

The pixels are provided to overlap at least one of the first signal line SL1 or the second signal line SL2 and emit predetermined light to display an image. The light emission area EA (shown in FIG. 3) can correspond to an area, which emits light, in the pixel P.

Each of the red sub-pixel SP1 (or first sub-pixel SP1), the white sub-pixel SP2 (or second sub-pixel SP2), the blue sub-pixel SP3 (or third sub-pixel SP3), and the green sub-pixel SP4 (or fourth sub-pixel SP4) can comprise at least one or more light emission areas. The at least one light emission area of each of the sub-pixels SP1, SP2, SP3, SP4 can have the same shape and size, but is not necessarily limited thereto.

Referring to FIG. 2, the first subpixel SP1, the second subpixel SP2, the third subpixel SP3, and the fourth subpixel SP4 can be arranged in a row in the first direction (Y-axis direction), and the transmissive area TA can be arranged adjacent to each of the first subpixel SP1, the second subpixel SP2, the third subpixel SP3, and the fourth subpixel SP4 in the second direction (X-axis direction). However, it is not limited to this, and the arrangement structure of the plurality of subpixels SP can be arranged in various ways depending on the circuit design. For example, the plurality of subpixels SP can include the first subpixel SP1 and the third subpixel SP3 spaced apart in the first direction (Y-axis direction), and the second subpixel SP2 and the fourth subpixel SP4 spaced apart in the second direction (X-axis direction) from each of the first subpixel SP1 and the third subpixel SP3. The transmissive area TA can be arranged adjacent to each of the second subpixel SP2 and the fourth subpixel SP4 in the second direction (X-axis direction). Hereinafter, one example in which each of the first to fourth subpixels SP1, SP2, SP3, and SP4 is arranged in a row in the first direction (Y-axis direction) as shown in FIG. 2 will be described.

FIG. 3 is a schematic cross-sectional view of the line I-I′ shown in FIG. 2.

Referring to FIG. 3, the transparent display apparatus 100 according to one embodiment of the present disclosure can have a non-light emission area NEA provided between the transmissive area TA and the plurality of subpixels SP1, SP2, SP3, SP4 (or the plurality of light emission areas EA) on a substrate 110. In addition, the transparent display apparatus 100 according to one embodiment of the present disclosure can have the non-light emission area NEA partially provided in the transmissive area TA. For example, the non-light emission area NEA can be formed at a position corresponding to the planarization layer 130 (or island OC) on an auxiliary line 120 in the transmissive area TA.

The non-light emission area NEA can refer to an area that is provided in the display area DA and does not emit light, and can be expressed as a dead zone because it does not emit light. The dead zone according to one example can be an area in which a black matrix and/or a bank is provided, but is not limited thereto, and can refer to an area in which light is not emitted.

The non-light emission area NEA and/or the light emission area EA can have the plurality of lines, for example, first signal lines SL1 and second signal lines SL2 can be disposed. The first signal lines SL1 according to one example can include a pixel power line, a common power line EVSS, a reference line, and the plurality of data lines, which are extending in the first direction (Y-axis direction). The second signal lines SL2 according to one example can include the gate line GL disposed extending in the second direction (X-axis direction).

The transparent display apparatus 100 according to one embodiment of the present disclosure can include an auxiliary line 120, a planarization layer 130, a blocking portion 140, and a plurality of undercut portions 150.

The auxiliary line 120 according to one example is arranged on the substrate 110 and can overlap the transmissive area TA. The auxiliary line 120 is for auxiliary supplying a common voltage (or common power) to the cathode electrode 117. Accordingly, as shown in FIG. 3, the auxiliary line 120 can be extended from the transmissive area TA toward one (e.g., the third sub-pixel SP3) of the plurality of sub-pixels SP and connected to the common power line EVSS. Further, the cathode electrode 117 can be connected to the auxiliary line 120 in the undercut portion 150. Since the auxiliary line 120 is configured to be connected to the common power line EVSS, it can be expressed in terms of a branch line of the common power line.

For example, in the case of a general large-area transparent display apparatus, a voltage drop can occur when a common voltage supplied from an edge portion of the display panel is applied to a center portion of the display panel. Therefore, the general large-area transparent display apparatus has a problem in that a luminance of the image emitted from the edge and center of the display panel is uneven. In addition, general large-area transparent display apparatus has the problem of increasing overall power consumption because the display panel must be driven at high power to solve the problem of uneven luminance of the image as above.

However, in the transparent display apparatus 100 according to one embodiment of the present disclosure, the auxiliary line 120 is arranged to overlap the transmissive area TA included in the plurality of pixels P, so that the cathode electrode 117 can receive a common voltage through the auxiliary line 120 even in the central portion of the display panel. Accordingly, the transparent display apparatus 100 according to one embodiment of the present disclosure is provided so that the common voltage difference between the edge portion and the center portion of the display panel is small or does not occur, so that the luminance of the image emitted from the edge portion and the center portion of the display panel can be provided uniformly.

In addition, since the transparent display apparatus 100 according to one embodiment of the present disclosure is provided such that the cathode electrode 117 and the auxiliary line 120 are in contact at the undercut portion 150 in the transmissive area TA, the voltage drop at the center portion of the display panel can be prevented, so that the luminance of the edge portion and the center portion of the display panel can be made uniform with low power, and thus the overall power consumption can be reduced.

The planarization layer 130 according to one example can be placed on the auxiliary line 120. The planarization layer 130 according to one example is for forming a plurality of undercut portions 150. Accordingly, the planarization layer 130 can be placed on the auxiliary line 120 while having a predetermined width and thickness. The plurality of undercut portions 150 are intended to disconnect the encapsulation layer 118. The plurality of undercut portions 150 can mean a plurality of spaces (or at least one space) formed between the auxiliary line 120 and the planarization layer 130. Accordingly, the planarization layer 130 can be arranged to be spaced apart from the auxiliary line 120 in the third direction (Z-axis direction). For example, since a plurality of inorganic films 111 and the blocking portion 140 can be arranged on the auxiliary line 120, the planarization layer 130 can be arranged spaced apart from the auxiliary line 120 in the third direction (Z-axis direction).

Meanwhile, in the transparent display apparatus 100 according to one embodiment of the present disclosure, the planarization layer 130 (or island OC) on the auxiliary line 120 can function as a support that supports the opposing substrate (or upper substrate). For example, as shown in FIG. 3, the planarization layer 130 on the auxiliary line 120 can function as a support for maintaining a cell gap (or interval) between the substrate 110 and the opposing substrate 200 together with a plurality of inorganic films 111, a pattern structure PS, a spacer SPC, at least one color filter CF, and a black matrix BM. Therefore, the transparent display apparatus 100 according to one embodiment of the present disclosure can have improved reliability against external impact (or external force) without a separate support.

In addition, when the transparent display apparatus 100 according to one embodiment of the present disclosure is implemented as a large-area transparent display apparatus, since a support is provided for each of a plurality of transmissive areas TA, the opposing substrate (or upper substrate) can be prevented from sagging toward the substrate 110 (or lower substrate 110).

The plurality of inorganic films 111 can include a first inorganic film IL1 and a second inorganic film IL2. The first inorganic film IL1 according to one example can include a second passivation layer 111d. The second inorganic film IL2 according to one example can be disposed below the first inorganic film IL1 and can include an interlayer insulating layer 111b and a first passivation layer 111c. The plurality of inorganic films 111 can further include a gate insulating layer 111a arranged between an active layer 112a and a gate electrode 112b of a thin film transistor. As shown in FIG. 3, the interlayer insulating layer 111b, the first passivation layer 111c, the blocking portion 140, and the second passivation layer 111d can be arranged between the planarization layer 130 and the auxiliary line 120.

The planarization layer 130 can be placed apart from the overcoat layer 113 that is placed to partially overlap the light emission area EA of each of the plurality of subpixels SP. For example, the planarization layer 130 can be arranged to overlap the transmissive area TA, and thus can be arranged to be spaced apart from the overcoat layer 113. The planarization layer 130 can be formed together with the overcoat layer 113 using the same material and process. Accordingly, the planarization layer 130 can be placed on the same layer as the overcoat layer 113. For example, the planarization layer 130 can be disposed on the second passivation layer 111d. In this disclosure, different terms and drawing symbols are used to distinguish the planarization layer 130 from the overcoat layer 113. Since the planarization layer 130 is provided in an island shape spaced apart from the overcoat layer 113, it can be expressed by the term island OC.

According to one example, the blocking portion 140 is provided to form the plurality of undercut portions 150 (or the second undercut portion 152). The blocking portion 140 can be arranged between the planarization layer 130 and the auxiliary line 120. For example, the blocking portion 140 can be placed between the first passivation layer 111c and the second passivation layer 111d. The blocking portion 140 can be formed on the same layer as the gate electrode 112b or the source electrode 112c, but is not limited thereto. The blocking portion 140 can be arranged on a layer other than an upper surface of the first passivation layer 111c. The blocking portion 140 can be formed of a material that is not etched by an etchant that etches the plurality of inorganic films 111. For example, the blocking portion 140 can be formed of a single or plurality of layers of metal material.

A width W1 of the blocking portion 140 can be provided to be wider than a width of the first inorganic film IL1 (or a width of the second inorganic film IL2). This is because the blocking portion 140 is formed of a metal material and is not etched by an etchant that etches the inorganic film, so that one undercut portion 150 (or a first undercut portion 151) can be formed on the blocking portion 140, and another undercut portion 150 (or a second undercut portion 152) can be formed below the blocking portion 140. Accordingly, as shown in FIG. 3, the first inorganic film IL1 (or the second passivation layer 111d) narrower than the blocking portion 140 can be arranged between the planarization layer 130 and the blocking portion 140. In addition, the second inorganic film IL2 (or the interlayer insulating layer 111b and the first passivation layer 111c) narrower than the blocking portion 140 can be arranged between the blocking portion 140 and the auxiliary line 120.

Meanwhile, since the auxiliary line 120 extends from the transmissive area TA toward the light emission area EA and is connected to the common power line EVSS, the width W1 of the blocking portion 140 can be provided to be narrower than a width W2 of the auxiliary line 120.

According to one example, the plurality of undercut portions 150 can be partially arranged on the upper side and the lower side of the blocking portion 140. As described above, the plurality of undercut portions 150 can be formed between the auxiliary line 120 and the planarization layer 130 so that the encapsulation layer 118 is disconnected. The plurality of undercut portions 150 can be formed by partially etching the first inorganic film IL1 between the planarization layer 130 and the blocking portion 140, and partially etching the second inorganic film IL2 between the blocking portion 140 and the auxiliary line 120. Accordingly, a predetermined space can be formed on each of a left side and a right side of the first inorganic film IL1 (or the second passivation layer 111d) on an upper surface of the blocking portion 140 based on FIG. 3. Further, based on FIG. 3, a predetermined space can be formed on each of a left side and a right side of the second inorganic film IL2 (or the interlayer insulating layer 111b and the first passivation layer 111c) on a lower surface of the blocking portion 140.

Therefore, the transparent display apparatus 100 according to one embodiment of the present disclosure can be provided with a double undercut structure in which the plurality of undercut portions 150 are provided on each of the upper side and the lower side of the blocking portion 140, thereby overlapping the plurality of undercut portions 150 in the third direction (Z-axis direction). Thus, since the transparent display apparatus 100 according to one embodiment of the present disclosure can reliably cut the encapsulation layer 118 through the deep double undercut structure, even if an external impact is transmitted to the encapsulation layer 118 on the planarization layer 130 through the spacer SPC and a crack occurs, the crack can be provided so that it does not propagate to the encapsulation layer 118 covering the light-emitting element layer E of each of the plurality of subpixels SP. Here, the light-emitting element layer E can mean a light-emitting element that emits light in each of the plurality of subpixels SP.

As a result, the transparent display apparatus 100 according to one embodiment of the present disclosure can maximize the disconnection of the encapsulation layer 118 through the plurality of undercut portions 150, so that crack propagation through the encapsulation layer 118 can be blocked. Furthermore, in the transparent display apparatus 100 according to one embodiment of the present disclosure, cracks do not propagate in the encapsulation layer 118 covering the light-emitting elements (or light-emitting element layers E) of each of the plurality of subpixels SP, so that the encapsulation layer 118 can maintain a state in which the light-emitting elements (or light-emitting element layers E) are sealed, and thus moisture penetration into the light-emitting elements (or light-emitting element layers E) can be prevented.

Meanwhile, each of the plurality of spacers SPC can be placed in the transmissive area TA. In one embodiment of the present disclosure, the transparent display apparatus 100 can include at least one transmissive area TA for each of the plurality of pixels P. Accordingly, since the transparent display apparatus 100 according to one embodiment of the present disclosure can be provided with each of the plurality of spacers SPC in each of the plurality of transmissive areas TA, the cell gap between the substrate 110 and the opposing substrate 200 can be firmly maintained, so that not only can the defect rate be reduced, but also the robustness against external force can be improved.

Hereinafter, with reference to FIG. 3 again, the structure of each of the plurality of sub-pixels SPs will be described in detail.

Referring to FIG. 3, the transparent display apparatus 100 according to one embodiment of the present disclosure can include a buffer layer BL, a plurality of inorganic film layers 111, a thin film transistor 112, an overcoat layer 113, a pixel electrode 114, a bank 115, an organic light emitting layer 116, a cathode electrode 117, an encapsulation layer 118, a filling layer 119, a color filter CF, a black matrix BM., and an upper organic film UO.

In more detail, each of the subpixels SP according to one embodiment can include a plurality of inorganic film layers 111 provided on an upper surface of a buffer layer BL, including a gate insulating layer 111a, an interlayer insulating layer 111b, a first passivation layer 111c, a second passivation layer 111d, an overcoat layer 113 provided on the plurality of inorganic film layers 111, a pixel electrode 114 provided on the overcoat layer 113, a bank 115 covering an edge of the pixel electrode 114, an organic light emitting layer 116 on the pixel electrode 114 and the bank 115, an cathode electrode 117 on the organic light emitting layer 116, an encapsulation layer 118 on the cathode electrode 117, a filling layer 119 on the encapsulation layer 118, a color filter CF and a black matrix BM on the filling layer 119, an upper organic film UO covering the color filter CF and the black matrix BM.

The thin film transistor 112 for driving the subpixel SP can be disposed on the plurality of inorganic film layers 111. The plurality of inorganic film layers 111 can also be expressed in terms of an inorganic film layers or a circuit element layers. The buffer layer BL can be included in the plurality of inorganic film layers 111 together with the gate insulating layer 111a, the interlayer insulating layer 111b, the first passivation layer 111c, and the second passivation layer 111d. The pixel electrode 114, the organic light emitting layer 116 and the cathode electrode 117 can be included in the light emitting element layer E.

The buffer layer BL can be formed between the substrate 110 and the gate insulating layer 111a to protect the thin film transistor 112. The buffer layer BL can be disposed on the entire surface (or front surface) of the substrate 110. However, it is not limited thereto, and the buffer layer BL can be partially disposed on the substrate 110. As shown in FIG. 3, the common power line EVSS can be disposed in a portion where the buffer layer BL is not disposed. However, it is not limited thereto, and the buffer layer BL can be provided to partially cover the common power line EVSS.

The common power line EVSS can be spaced apart from the thin film transistor 112 and can be arranged to overlap the light emission area EA and/or the non-light emission area NEA of each of the plurality of subpixels SP. The auxiliary line 120 can be connected and arranged to the common power line EVSS. Accordingly, the auxiliary line 120 can receive a common voltage from the common power line EVSS. According to one example, the auxiliary line 120 can be formed together with the common power line EVSS. The buffer layer BL can also serve to block a material contained in the substrate 110 from diffusing into the transistor layer during a high-temperature process during the manufacturing process of the thin film transistor. Optionally, the buffer layer BL can be omitted in some cases.

The thin film transistor 112 (or a drive transistor) according to one example can include an active layer 112a, a gate electrode 112b, a source electrode 112c, and a drain electrode 112d.

The active layer 112a can include a channel area, a drain area and a source area, which are formed in a thin film transistor area of a circuit area of the subpixel SP. The drain area and the source area can be spaced apart from each other with the channel area interposed therebetween.

The active layer 112a can be formed of a semiconductor material based on any one of amorphous silicon, polycrystalline silicon, oxide and organic material.

The gate insulating layer 111a can be formed on the channel area of the active layer 112a. As one example, the gate insulating layer 111a can be formed in an island shape only on the channel area of the active layer 112a, or can be formed on an entire front surface of the substrate 110 or the buffer layer BL, which includes the active layer 112a.

The gate electrode 112b can be formed on the gate insulating layer 111a to overlap the channel area of the active layer 112a.

The interlayer insulating layer 111b can be formed on the gate electrode 112b and the drain area and the source area of the active layer 112a. As in FIG. 3, the interlayer insulating layer 111b can be formed in an entire light emission area, in which light is emitted to the subpixel SP. However, embodiments of the present disclosure are not limited thereto, the interlayer insulating layer 111b can be patterned between the drain electrode 112d and the gate electrode 112b and drain region of the active layer 112a and can be arranged in an island shape, and moreover, can be patterned between the source electrode 112c and the gate electrode 112b and source region of the active layer 112a and can be arranged in an island shape.

The source electrode 112c can be electrically connected to the source area of the active layer 112a through a source contact hole provided in the interlayer insulating layer 111b overlapped with the source area of the active layer 112a. The drain electrode 112d can be electrically connected to the drain area of the active layer 112a through a drain contact hole provided in the interlayer insulating layer 111b overlapped with the drain area of the active layer 112a.

The drain electrode 112d and the source electrode 112c can be made of the same metal material. For example, each of the drain electrode 112d and the source electrode 112c can be made of a single metal layer, a single layer of an alloy or a multi-layer of two or more layers, which is the same as or different from that of the gate electrode.

In addition, the circuit area can further include first and second switching thin film transistors disposed together with the thin film transistor 112, and a capacitor. Since each of the first and second switching thin film transistors is provided on the circuit area of the subpixel SP to have the same structure as that of the thin film transistor 112, its description will be omitted. The capacitor can be provided in an overlap area between the gate electrode 112b and the source electrode 112c of the thin film transistor 112, which overlap each other with the interlayer insulating layer 111b interposed therebetween.

Additionally, in order to prevent a threshold voltage of the thin film transistor provided in a pixel area from being shifted by light, the display panel or the substrate 110 can further include a light shielding layer LS provided below the active layer 112a of at least one of the thin film transistor 112, the first switching thin film transistor or the second switching thin film transistor. The light shielding layer can be disposed between the substrate 110 and the active layer 112a to shield light incident on the active layer 112a through the substrate 110, thereby minimizing a change in the threshold voltage of the transistor due to external light. Further, since the light shielding layer is provided between the substrate 110 and the active layer 112a, the thin film transistor can be prevented from being seen by a user.

The first passivation layer 111c can be provided on the substrate 110 to cover the pixel area. The first passivation layer 111c covers a drain electrode 112d, a source electrode 112c and a gate electrode 112b of the thin film transistor 112, and the buffer layer BL. The first passivation layer 111c can be formed over the circuit area and the light emission area. The first passivation layer 111c can be omitted.

The second passivation layer 111d can be provided on the substrate 110 to cover the first passivation layer 111c. The second passivation layer 111d can be provided to cover a connection electrode CE disposed on the first passivation layer 111c. According to one example, the connection electrode CE is for connecting the source electrode 112c and the pixel electrode 114. The connection electrode CE can be connected to the source electrode 112c through a contact hole formed in the first passivation layer 111c and to the pixel electrode 114 through a contact hole formed in the second passivation layer 111d. The connection electrode CE and the second passivation layer 111d can be omitted.

The overcoat layer 113 can be provided on the substrate 110 to cover the second passivation layer 111d. When the second passivation layer 111d is omitted, the overcoat layer 113 can be provided on the substrate 110 to cover the circuit area (or the thin film transistor 112). The overcoat layer 113 can be formed in the circuit area CA in which the thin film transistor 112 is disposed and the light emission area EA. In addition, the overcoat layer 113 can be formed in the other non-display area NDA except a pad area PA of the non-display area NDA and the entire display area DA. For example, the overcoat layer 113 can include an extension portion (or an enlarged portion) extended or enlarged from the display area DA to the other non-display area NDA except the pad area PA. Therefore, the overcoat layer 113 can have a size relatively wider than that of the display area DA.

The overcoat layer 113 according to one example can be formed to have a relatively thick thickness, thereby providing a flat surface on the display area DA and the non-display area NDA. For example, the overcoat layer 113 can be made of an organic material such as photo acryl, benzocyclobutene, polyimide and fluorine resin.

On the other hand, the upper surface of the overcoat layer 113 can be provided flatly. Accordingly, the pixel electrodes 114 on the overcoat layer 113 can also be provided flatly, and the organic light emitting layer 116 and the cathode electrode 117 formed thereon can also be provided flatly. Since the pixel electrode 114, the organic light emitting layer 116, the cathode electrode 117, for example, the light emitting element layer E is provided to be flat in the light emission area EA, a thickness of each of the pixel electrode 114, the organic light emitting layer 116 and the cathode electrode 117 in the light emission area EA can be uniformly formed. Therefore, the organic light emitting layer 116 can be uniformly emitted without deviation in the light emission area EA.

The pixel electrodes 114 according to one example can be formed on the overcoat layer 113. The pixel electrode 114 can be connected to a drain electrode or a source electrode of the thin film transistor 112 through a contact hole passing through the overcoat layer 113 and the second passivation layer 111d. The one edge portion of the pixel electrode 114 can be covered by the bank 115. The pixel electrode 114 can be made of at least one of a transparent metal material or a semi-transmissive metal material.

Since the transparent display apparatus 100 according to one embodiment of the present disclosure is top-emission type, the pixel electrodes 114 can be made of a highly reflective metallic material or a stacked structure of a highly reflective metallic material and a transparent metallic material. For example, the first electrode 114 can be formed of a metal material having high reflectance, such as a stacked structure (Ti/Al/Ti) of aluminum and titanium, a stacked structure (ITO/Al/ITO) of aluminum and ITO, an Ag alloy, and a stacked structure (ITO/Ag alloy/ITO) of Ag alloy and ITO. The Ag alloy can be an alloy such as silver (Ag), palladium (Pd), and copper (Cu).

Meanwhile, the material constituting the pixel electrode 114 can include MoTi. The pixel electrode 114 can be a first electrode or an anode electrode.

The bank 115 can be an area, which does not emit light, and disposed on one side of the light emission area EA of each of the plurality of sub-pixels SP. For example, the bank 115 can be disposed in the non-light emission area NEA. The bank 115 can be formed to cover a portion where the edge of the pixel electrode 114. Accordingly, the bank 115 can prevent the pixel electrode 114 and the cathode electrode 117 in the edge of the pixel electrode 114. The exposed portion of the pixel electrode 114 that is not covered by the bank 115 can be included in the light emitting portion (or light emission area EA).

After the bank 115 is formed, an organic light emitting layer 116 can be formed to cover the pixel electrodes 114 and the bank 115. Thus, the bank 115 can be provided between the pixel electrodes 114 and the organic light emitting layer 116. The bank 115 can be expressed in terms of a pixel-defining membrane. The bank 115 according to one example can comprise organic material and/or inorganic material.

The organic light emitting layer 116 can be formed on the pixel electrodes 114 and the bank 115. According to one example, the organic light emitting layer 116 can be disposed in the light emission area EA and the non-light emission area NEA. The organic light emitting layer 116 can be provided between the pixel electrode 114 and the cathode electrode 117. Thus, when a voltage is applied to each of the pixel electrode 114 and the cathode electrode 117, an electric field is formed between the pixel electrode 114 and the cathode electrode 117. Therefore, the organic light emitting layer 116 can emit light. The organic light emitting layer 116 can be formed of a plurality of subpixels SP and a common layer provided on the bank 115.

The organic light emitting layer 116 according to an embodiment can be provided to emit white light. The organic light emitting layer 116 can include a plurality of stacks which emit lights of different colors. For example, the organic light emitting layer 116 can include a first stack, a second stack, and a charge generating layer (CGL) provided between the first stack and the second stack. The light emitting layer can be provided to emit the white light, and thus, each of the plurality of subpixels SP can include a color filter CF suitable for a corresponding color.

The first stack can be provided on the pixel electrode 114 and can be implemented a structure where a hole injection layer (HIL), a hole transport layer (HTL), an emission layer (EML(B)), and an electron transport layer (ETL) are sequentially stacked.

The charge generating layer can supply an electric charge to the first stack and the second stack. The charge generating layer can include an N-type charge generating layer for supplying an electron to the first stack and a P-type charge generating layer for supplying a hole to the second stack. The N-type charge generating layer can include a metal material as a dopant.

The second stack can be provided on the first stack and can be implemented in a structure where a hole transport layer (HTL), a yellow-green (YG) emission layer (EML(YG)), and an electron injection layer (EIL) are sequentially stacked.

In the display apparatus 100 according to an embodiment of the present disclosure, because the organic light emitting layer 116 is provided as a common layer, the first stack, the charge generating layer, and the second stack can be arranged all over the plurality of subpixels SP. The organic light emitting layer 116, according to another example, can be provided in a three-stacked structure or a four-stacked structure, depending on the number of stacks stacked.

The cathode electrode 117 can be formed on the organic light emitting layer 116. The cathode electrode 117 can be disposed in the light emission area EA and the non-light emission area NEA. The cathode electrode 117 according to one example can include a metal material. The cathode electrode 117 can reflect the light emitted from the organic light emitting layer 116 in the plurality of subpixels SP toward the lower surface of the substrate 110. Therefore, the display apparatus 100 according to one embodiment of the present disclosure can be implemented as a bottom emission type display apparatus.

Since the transparent display apparatus 100 according to one embodiment of the present disclosure is top-emission type, the cathode electrodes 117 can be formed of a transparent conductive material TCO such as ITO, IZO, that is capable of transmitting light or a semi-transmissive conductive material TMCM such as magnesium (Mg), silver (Ag), or an alloy of magnesium (Mg) and silver (Ag). Such cathode electrodes 117 can be referred in terms of a second electrode, an opposing electrode.

The encapsulation layer 118 is formed on the cathode electrode 117. According to one example, the encapsulation layer 118 serves to prevent oxygen or moisture from penetrating into the organic light-emitting layer 116 and the cathode electrode 117. To this end, the encapsulation layer 118 can be provided to seal the light emitting element layer E in each of the plurality of subpixels SP. For example, the encapsulation layer 118 can be provided on the substrate 110 to cover the light emission area EA and the non-light emission area NEA. In addition, the encapsulation layer 118 can also be provided in the transmissive area TA. For example, the encapsulation layer 118 can be deposited on the entire surface of the substrate 110. The encapsulation layer 118 according to one example can be provided with an inorganic material, but is not limited thereto, and can be provided with an organic material or can be provided with a structure in which an organic material and an inorganic material are laminated. The encapsulation layer 118 can be disconnected at the plurality of undercut portions 150.

The filling layer 119 is formed on the encapsulation layer 118. The filling layer 119 can play a role in preventing oxygen or moisture from penetrating into the organic light-emitting layer 116 and the cathode electrode 117, similar to the encapsulation layer 118. The filling layer 119 according to one example can be configured to include a getter capable of absorbing oxygen or moisture. Alternatively, the filling layer 119 can be provided with a plurality of layers including at least one inorganic film layer and at least one organic film layer.

On the other hand, the filling layer 119 can be disposed not only in the light emission area EA but also in the non-light emission area NEA. The filling layer 119 can be disposed between the encapsulation layer 118 and the opposing substrate 200.

A color filter CF and a black matrix BM can be disposed between the filling layer 119 and the opposing substrate 200. As mentioned above, the white light emitting portion SP2 can not be provided with a color filter since the organic light emitting layer 116 emits white light. On the other hand, the red sub-pixel SP1 can be provided with the third color filter CF3 (or red color filter CF3) between the filling layer 119 and the opposing substrate 200. The blue sub-pixel SP3 can be provided with the first color filter CF1 (or blue color filter CF1) between the filling layer 119 and the opposing substrate 200. The green sub-pixel SP4 can be provided with the second color filter CF2 (or green color filter CF2) between the filling layer 119 and the opposing substrate 200. As shown in FIG. 3, at least one color filter CF can be placed on the black matrix BM in the transmissive area TA.

On the other hand, the black matrix BM can be provided between the plurality of sub-pixels SP1, SP2, SP3, SP4 to prevent color mixing and/or light leakage. The black matrix BM can comprise a black colored material and can be disposed overlapping the bank 115. The area provided with the black matrix BM and/or the bank 115 can be a dead zone or the non-light emission area. The black matrix BM according to one example can be formed on an opposing substrate 200 to overlap at least a portion of the bank 115, thereby reducing the cell gap between the organic light emitting layer 116 and the opposing substrate 200 to prevent mixing of sub-pixels.

In addition, as shown in FIG. 3, the black matrix BM according to one example partially overlaps at least one color filter CF and the planarization layer 130, and is positioned between the spacer 140 and the opposing substrate 200, thereby functioning as a support that maintains a cell gap (or a gap) between the substrate 110 and the opposing substrate 200.

The upper organic film UO can be placed between the spacer SPC and at least one color filter CF. The upper organic film UO can be provided on a front surface of the opposing substrate 200 so as to cover at least one color filter CF and partially contact the opposing substrate 200. Accordingly, the upper organic film UO can prevent at least one color filter CF and the black matrix BM from being torn off or lifted off from the opposing substrate 200.

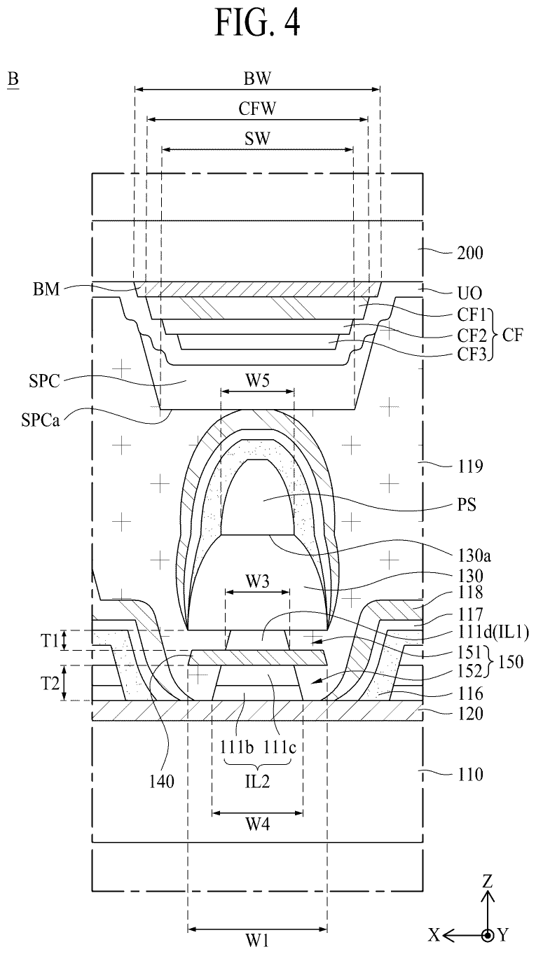

FIG. 4 is a schematic enlargement of portion B of FIG. 3.

Hereinafter, with reference to FIGS. 3 and 4, the planarization layer 130, the blocking portion 140, and the plurality of undercut portions 150 included in the transparent display apparatus 100 according to one embodiment of the present disclosure will be described in more detail. In addition, a pattern structure PS and a spacer SPC included in the transparent display apparatus 100 according to one embodiment of the present disclosure will be described.

Referring to FIGS. 3 and 4, in the transparent display apparatus 100 according to one embodiment of the present disclosure, the plurality of undercut portions 150 can include a first undercut portion 151 and a second undercut portion 152.

According to one example, the first undercut portion 151 can be partially positioned between the blocking portion 140 and the planarization layer 130. For example, the first undercut portion 151 can be formed on each of the left and right sides of the first inorganic film IL1 (or the second passivation layer 111d) on an upper surface of the blocking portion 140. The first undercut portion 151 can be formed by partially etching the first inorganic film IL1 between the planarization layer 130 and the blocking portion 140 by an inorganic film etchant. Accordingly, the first inorganic film IL1 (or the second passivation layer 111d) can be arranged adjacent to the first undercut portion 151. Since the blocking portion 140 is formed of a metal material, it may not be etched by an inorganic film etchant. Accordingly, as shown in FIG. 4, a width W3 of the first inorganic film IL1 (or the second passivation layer 111d) between the planarization layer 130 and the blocking portion 140 can be formed to be narrower than a width W1 of the blocking portion 140.

According to one example, the second undercut portion 152 can be partially positioned between the blocking portion 140 and the auxiliary line 120. As shown in FIG. 3, the second undercut portion 152 can be positioned below the first undercut portion 151. Accordingly, the second undercut portion 152 can partially overlap the first undercut portion 151 in the third direction (Z-axis direction).

The second undercut portion 152 can be formed on each of the left and right sides of the second inorganic film IL2 (or the interlayer insulating layer 111b and the first passivation layer 111c respectively) on a lower surface of the blocking portion 140. The second undercut portion 152 can be formed by partially etching the second inorganic film IL2 (or the interlayer insulating layer 111b and the first passivation layer 111c) between the blocking portion 140 and the auxiliary line 120 by an inorganic film etchant. Accordingly, the second inorganic film IL2 (or each of the interlayer insulating layer 111b and the first passivation layer 111c) can be positioned adjacent to the second undercut portion 152. As described above, the blocking portion 140 can be formed of a metal material and thus may not be etched by the inorganic film etchant. Accordingly, as shown in FIG. 4, a width W4 of the second inorganic film IL2 (or each of the interlayer insulating layer 111b and the first passivation layer 111c) between the blocking portion 140 and the auxiliary line 120 can be provided to be narrower than the width W1 of the blocking portion 140.

However, since the second inorganic film IL2 (or the interlayer insulating layer 111b and the first passivation layer 111c respectively) is positioned closer to the substrate 110 than the first inorganic film IL1 (or the second passivation layer 111d), the degree of etching by the inorganic film etchant can be smaller. Accordingly, the width W4 of the second inorganic film IL2 (or each of the interlayer insulating layer 111b and the first passivation layer 111c) can be provided to be wider than a width W3 of the first inorganic film IL1 (or the second passivation layer 111d). As a result, the transparent display apparatus 100 according to one embodiment of the present disclosure can have a structural feature in which the width W4 of the second inorganic film IL2 (or each of the interlayer insulating layer 111b and the first passivation layer 111c) is wider than the width W3 of the first inorganic film IL1 (or the second passivation layer 111d) and narrower than the width W1 of the blocking portion 140.

Meanwhile, in the transparent display apparatus 100 according to one embodiment of the present disclosure, a thickness T2 of the second inorganic film IL2 can be provided to be thicker than a thickness T1 of the first inorganic film ILL. Since the plurality of undercut portions 150 are intended to disconnect the encapsulation layer 118, the plurality of inorganic films 111 under the planarization layer 130 can be formed by etching (or patterning) as deeply as possible. This is because the deeper the plurality of inorganic films 111 under the planarization layer 130 are etched (or patterned) in the third direction (Z-axis direction), the more reliably the encapsulation layer 118 deposited on the entire surface in the subsequent process can be disconnected. Accordingly, in the transparent display apparatus 100 according to one embodiment of the present disclosure, the second inorganic film IL2 that is thicker than the first inorganic film IL1 is partially etched (or patterned) under the first inorganic film (IL1), so that the encapsulation layer 118 can be reliably disconnected, and thus crack propagation to the encapsulation layer 118 covering the light-emitting element layer E can be blocked.

As a result, the transparent display apparatus 100 according to one embodiment of the present disclosure is provided so that the crack propagation path is doubly blocked by the plurality of undercut portions 150 (or the first undercut portion 151 and the second undercut portion 152), so that the lifespan of the light-emitting element (or the light-emitting element layer E) can be improved. Therefore, in the transparent display apparatus 100 according to one embodiment of the present disclosure, the light-emitting element (or light-emitting element layer E) can be driven at low power from the perspective of the entire lifespan of the light-emitting element, so that the overall power consumption can be reduced.

Referring again to FIG. 4, the cathode electrode 117 is positioned under the encapsulation layer 118 and can be in contact with the auxiliary line 120 at the second undercut portion 152. After the plurality of undercut portions 150 are formed, the organic light-emitting layer 116 and the cathode electrode 117 are sequentially deposited on the entire surface of the substrate 110, so that the organic light-emitting layer 116 and the cathode electrode 117 can be disconnected by the plurality of undercut portions 150. Accordingly, an end of the cathode electrode 117 extended from the light emitting element layer E can contact an upper surface of the auxiliary electrode 120 in the second undercut portion 152 formed in the transmissive area TA. Therefore, the cathode electrode 117 can receive a common voltage from the auxiliary electrode 120. Accordingly, in the transparent display apparatus 100 according to one embodiment of the present disclosure, the cathode electrode 117 and the auxiliary electrode 120 can be in contact with each of the plurality of transmissive areas TA arranged in the display area DA, so that voltage drop can be minimized or prevented at the center portion of the display panel.

Meanwhile, the cathode electrode 117 covering the planarization layer 130 (and the pattern structure PS) can be arranged spaced upward from the substrate 110. As shown in FIG. 4, the cathode electrode 117 covering the planarization layer 130 (and the pattern structure PS) can be arranged spaced apart from the substrate 110 with the plurality of undercut portions 150 interposed therebetween. In addition, the cathode electrode 117 can be formed discontinuously because it is disconnected by the plurality of undercut portions 150, and thus the cathode electrode 117 covering the planarization layer 130 (and the pattern structure PS) can be provided in an island shape.

As described above, since the organic light-emitting layer 116 is deposited on an entire surface of the substrate 110 after the plurality of undercut portions 150 are formed, it can be disconnected by the plurality of undercut portions 150. Accordingly, an end of the organic light-emitting layer 116 extended from the light-emitting element layer E can contact an upper surface of the auxiliary electrode 120 at the second undercut portion 152 formed in the transmissive area TA. In contrast, the organic light-emitting layer 116 covering the planarization layer 130 (and the pattern structure PS) can be arranged spaced apart upward from the substrate 110. As shown in FIG. 4, the organic light-emitting layer 116 covering the planarization layer 130 (and the pattern structure PS) can be arranged spaced apart from the substrate 110 with the plurality of undercut portions 150 interposed therebetween.

The organic light-emitting layer 116 can be formed discontinuously because it is disconnected by the plurality of undercut portions 150. Accordingly, the transparent display apparatus 100 according to one embodiment of the present disclosure can prevent current from leaking from a light-emitting subpixel SP to a non-light-emitting subpixel SP by discontinuously providing the organic light-emitting layer 116. The organic light-emitting layer 116 covering the planarization layer 130 (and the pattern structure PS) can be provided in an island shape.

Meanwhile, in the case of a general transparent display apparatus, since only the organic light-emitting layer needs to be disconnected to prevent lateral leakage current, the depth of the undercut portion can be provided to be shallow.

In contrast, the transparent display apparatus 100 according to one embodiment of the present disclosure can be provided with a deep undercut portion through the plurality of undercut portions 150 overlapping in the third direction (Z-axis direction), thereby disconnecting not only the organic light-emitting layer 116 but also the cathode electrode 117 and the encapsulation layer 118. Therefore, the transparent display apparatus 100 according to one embodiment of the present disclosure can have the effect of not only preventing lateral leakage current by disconnection of the organic light-emitting layer 116, but also blocking crack propagation by disconnection of the encapsulation layer 118.

In addition, in the transparent display apparatus 100 according to one embodiment of the present disclosure, the cathode electrode 117 is formed discontinuously through the plurality of undercut portions 150 overlapping in the third direction (Z-axis direction), so that the cathode electrode 117 and the auxiliary line 120 can come into contact at the undercut portion 150 (or the second undercut portion 152), so that a voltage drop may not occur even at the center portion of the display panel.

Meanwhile, in the transparent display apparatus 100 according to one embodiment of the present disclosure, the depth of the undercut portion 150 is provided so deep that it disconnects the encapsulation layer 118, so that a width of the undercut portion 150 (for example, a distance from the second passivation layer 111d to the encapsulation layer 118 arranged obliquely on a right side with reference to FIG. 4) can also be provided to be wider.

The transparent display apparatus 100 according to one embodiment of the present disclosure can further include a pattern structure PS disposed on an upper surface 130a of the planarization layer 130.

According to one example, the pattern structure PS can be placed between the planarization layer 130 and the spacer SPC. Therefore, the pattern structure PS can function as a support supporting the substrate 110 and the opposing substrate 200. The pattern structure PS can be formed together with a bank 115 on the upper surface of the overcoat layer 113. Therefore, the pattern structure PS can be placed on the same layer as the bank 115. In this case, the pattern structure PS can be formed of the same material as the bank 115. Therefore, the transparent display apparatus 100 according to one embodiment of the present disclosure can form the pattern structure PS on the planarization layer 130 together with the bank 115 without a separate additional process, so that a support (or a part of the support) that maintains a cell gap (or interval) between the substrate 110 and the opposing substrate 200 can be formed without an increase in cost. However, the present invention is not limited thereto, and the pattern structure PS can be formed of a different material through a different process from the bank 115.

The pattern structure PS can be placed on the upper surface 130a of the planarization layer 130. Accordingly, the pattern structure PS can be covered by the organic light-emitting layer 116, the cathode electrode 117, and the encapsulation layer 118. Since the organic light-emitting layer 116, the cathode electrode 117, and the encapsulation layer 118 are provided discontinuously and disconnected by the plurality of undercut portions 150, each of the organic light-emitting layer 116 covering the pattern structure PS, the cathode electrode 117 covering the pattern structure PS, and the encapsulation layer 118 covering the pattern structure PS can be provided in an island shape.

Meanwhile, the transparent display apparatus 100 according to one embodiment of the present disclosure can further include a spacer SPC disposed between the encapsulation layer 118 covering the pattern structure PS and the upper organic film UO.

The spacer SPC according to one example is for maintaining a cell gap (or interval) between the substrate 110 and the opposing substrate 200. Therefore, the spacer SPC can be provided with a thickness capable of filling the gap between the encapsulation layer 118 covering the pattern structure PS and the upper organic film UO. According to one example, the spacer SPC can be formed on the upper organic film UO so as to overlap the black matrix BM after the upper organic film UO is formed on the opposing substrate 200. Thereafter, after the spacer SPC formed on the opposing substrate 200 is aligned with the pattern structure PS formed on the substrate 110, the opposing substrate 200 and the substrate 110 can be bonded to each other. Accordingly, as shown in FIGS. 3 and 4, the planarization layer 130 and the pattern structure PS can be sequentially stacked and arranged on a lower side based on the spacer SPC, and the at least one color filter CF and the black matrix BM can be overlapped and arranged on an upper side based on the spacer SPC.

Therefore, in the transparent display apparatus 100 according to one embodiment of the present disclosure, the plurality of inorganic films 111, the blocking portion 140, the planarization layer 130, the pattern structure PS, the spacer SPC, the upper organic film UO, the at least one color filter CF, and the black matrix BM can be overlapped on the auxiliary line 120, so that even if an external impact occurs, the cell gap (or interval) between the substrate 110 and the opposing substrate 200 can be maintained. Here, the plurality of inorganic films 111, the blocking portion 140, the planarizing layer 130, the pattern structure PS, the spacer SPC, the upper organic film UO, the at least one color filter CF, and the black matrix BM on the auxiliary line 120 arranged in the transmissive area TA can function as a support for maintaining the cell gap (or interval) between the substrate 110 and the opposing substrate 200.

The spacer SPC according to one example can be formed of an organic material, but is not necessarily limited thereto. If the cell gap (or interval) between the substrate 110 and the opposing substrate 200 can be maintained, the spacer SPC can be formed of an inorganic material or other material.

The spacer SPC is formed on the opposing substrate 200 and then can be brought into contact with the pattern structure PS (or the encapsulation layer 118 covering the pattern structure PS) on the substrate 110 through an alignment process. Accordingly, an upper surface SPCa of the spacer SPC can be brought into contact with the island-shaped encapsulation layer 118 covering the pattern structure PS. As a result, since the opposing substrate 200 is bonded to the substrate 110 through an alignment process, if a width of the spacer SPC is wide, alignment with the pattern structure PS becomes easier, so the tact time of the transparent display apparatus 100 can be shortened.

However, if the width of the spacer SPC is too wide, the spacer SPC can come into contact with a structure (for example, the bank 115 spaced apart from the pattern structure PS of FIG. 3 in the second direction (X-axis direction)) other than the pattern structure PS. In this case, cracks can occur in the encapsulation layer 118 on the bank 115 due to external impact, which can cause moisture penetration into the light-emitting element layer E, thereby lowering the reliability of the transparent display apparatus 100.

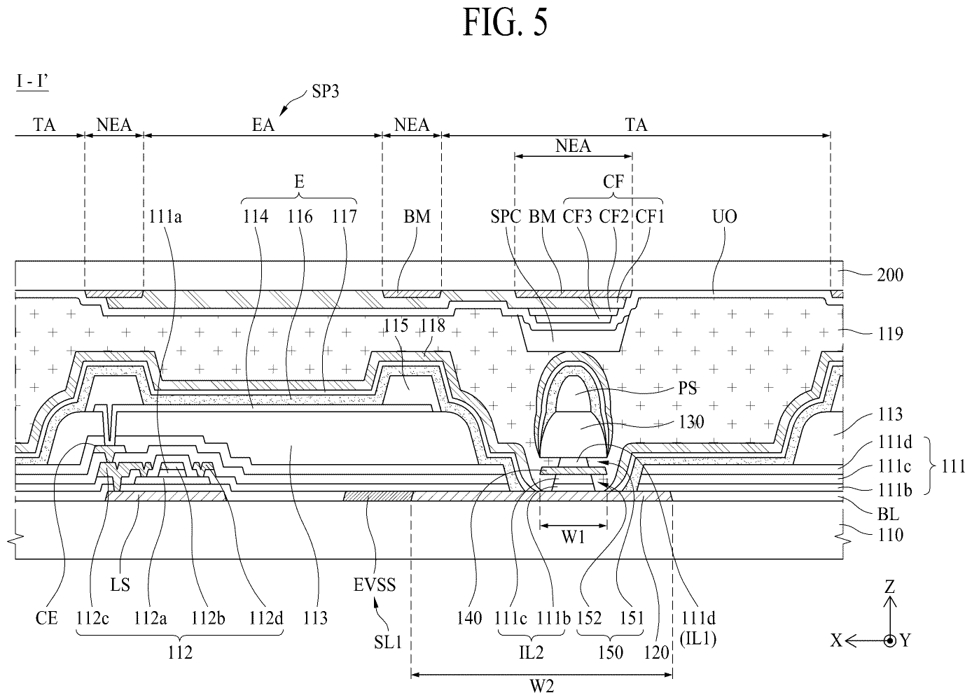

Therefore, in the transparent display apparatus 100 according to one embodiment of the present disclosure, a width SW of the spacer SPC (or the upper surface SPCa of the spacer SPC) can be provided so that it is easy to align with the pattern structure PS while not contacting other structures (e.g., the bank 115). For example, the width SW of the spacer SPC (or the upper surface SPCa of the spacer SPC) can be provided to be larger than a width W5 of the pattern structure PS and smaller than a width W2 (shown in FIG. 3) of the auxiliary line 120. Alternatively, the width SW of the spacer SPC (or the upper surface SPCa of the spacer SPC) can be provided to be larger than the width W5 of the pattern structure PS and equal to the width W1 of the planarization layer 130. Alternatively, the width SW of the spacer SPC (or the upper surface SPCa of the spacer SPC) can be provided to be larger than the width W5 of the pattern structure PS and to a degree that it can overlap with the plurality of undercut portions 150. In this case, the width SW of the spacer SPC (or the upper surface SPCa of the spacer SPC) can be larger than the width W1 of the planarization layer 130. In FIG. 5, although the width of the blocking portion 140 is indicated as W1, the width of the planarization layer 130 is also the same as the width of the blocking portion 140, so it can be described as W1.

As a result, the transparent display apparatus 100 according to one embodiment of the present disclosure is provided with the width W1 of the planarization layer 130 larger than the width W5 of the pattern structure PS and equal to or smaller than the width SW of the spacer SPC, as shown in FIG. 4, thereby reducing the alignment time between the opposing substrate 200 and the substrate 110 and preventing reliability degradation due to external impact (or external force).

Meanwhile, in the transparent display apparatus 100 according to one embodiment of the present disclosure, the width W5 of the pattern structure PS can be equal to or smaller than the width of the upper surface 130a of the planarization layer 130. If the width W5 of the pattern structure PS is larger than the width of the upper surface 130a of the planarization layer 130, the pattern structure PS protruding from the upper surface 130a of the planarization layer 130 can be lost during the etching of the inorganic film (or during the cleaning of the substrate 110). Accordingly, in the transparent display apparatus 100 according to one embodiment of the present disclosure, the width W5 of the pattern structure PS is provided to be equal to or smaller than the width of the upper surface 130a of the planarization layer 130, so that loss of the pattern structure PS can be prevented, thereby reducing the defect rate.

Referring again to FIG. 4, in the transparent display apparatus 100 according to one embodiment of the present disclosure, a width CFW of at least one color filter CF can be provided to be narrower than the width BW of the black matrix BM. For example, as shown in FIG. 4, a first color filter CF1 can be placed on the black matrix BM, a second color filter CF2 can be placed on the first color filter CF1, and a third color filter CF3 can be placed on the second color filter CF2. For example, on the black matrix BM, the first color filter CF1, the second color filter CF2, and the third color filter CF3 can be sequentially stacked and arranged in a direction from the opposing substrate 200 toward the substrate 110. Here, a width CFW of the first color filter CF1 in contact with the black matrix BM can be provided to be narrower than the width BW of the black matrix BM. In addition, a width of the second color filter CF2 in contact with the first color filter CF1 can be provided narrower than the width CFW of the first color filter CF1. In addition, a width of the third color filter CF3 in contact with the second color filter CF2 can be provided narrower than the width of the second color filter CF2. Accordingly, the widths of each of the first color filter CF1, the second color filter CF2, and the third color filter CF3 can be provided to become narrower in the direction from the opposing substrate 200 toward the substrate 110. However, the present invention is not necessarily limited thereto, and the width of the first color filter CF1 can be provided to be narrower than the width of the second color filter CF2. In this case, the second color filter CF2 can be in contact with the black matrix BM while covering the first color filter CF1. However, even in this case, the width of the second color filter CF2 can be provided to be narrower than the width of the black matrix BM.

If the width of the color filter CF in contact with the black matrix BM is wider than the width of the black matrix BM, light can be emitted through the color filter that does not overlap the black matrix, which can cause color mixing.

Therefore, in the transparent display apparatus 100 according to one embodiment of the present disclosure, color mixing can be prevented by providing the width CFW of at least one color filter CF narrower than the width BW of the black matrix BM. Additionally, the transparent display apparatus 100 according to one embodiment of the present disclosure can be provided such that the planarization layer 130 overlaps the first color filter CF1, the second color filter CF2, and the third color filter CF3. Accordingly, the planarization layer 130 and the first to third color filters CF1, CF2, CF3 can function as a support for maintaining the cell gap (or interval) between the substrate 110 and the opposing substrate 200.

FIG. 5 is a schematic cross-sectional view showing another example of a color filter illustrated in FIG. 3.

Referring to FIG. 5, in the transparent display apparatus 100 according to one embodiment of the present disclosure, at least one color filter CF among the color filters can be arranged to extend to one subpixel SP (or light emission area EA) among the plurality of subpixels SP. Here, the at least one color filter can mean a color filter CF arranged in the transmissive area TA.

For example, the first color filter CF1 functioning as a support (or the first color filter CF1 overlapping the transmissive area TA) can be provided to extend toward the third sub-pixel SP3 and cover a light emission area EA of the third sub-pixel SP3. Accordingly, the first color filter CF1 overlapping the transmissive area TA and the color filter CF1 arranged in the light emission area EA of the third subpixel SP3 can be formed integrally. In this case, the first color filter CF1 can be in contact with the opposing substrate 200 while covering the black matrix BM in the non-light emission area NEA between the light emission area EA and the transmissive area TA.

Therefore, in the case of the transparent display apparatus 100 according to FIG. 5, at least one color filter CF overlapping the transmissive area TA is arranged to extend to one (or the light emission area EA) of the plurality of subpixels SP, so that the black matrix BM between the transmissive area TA and the light emission area EA can be prevented from being torn off or lifted from the opposing substrate 200.

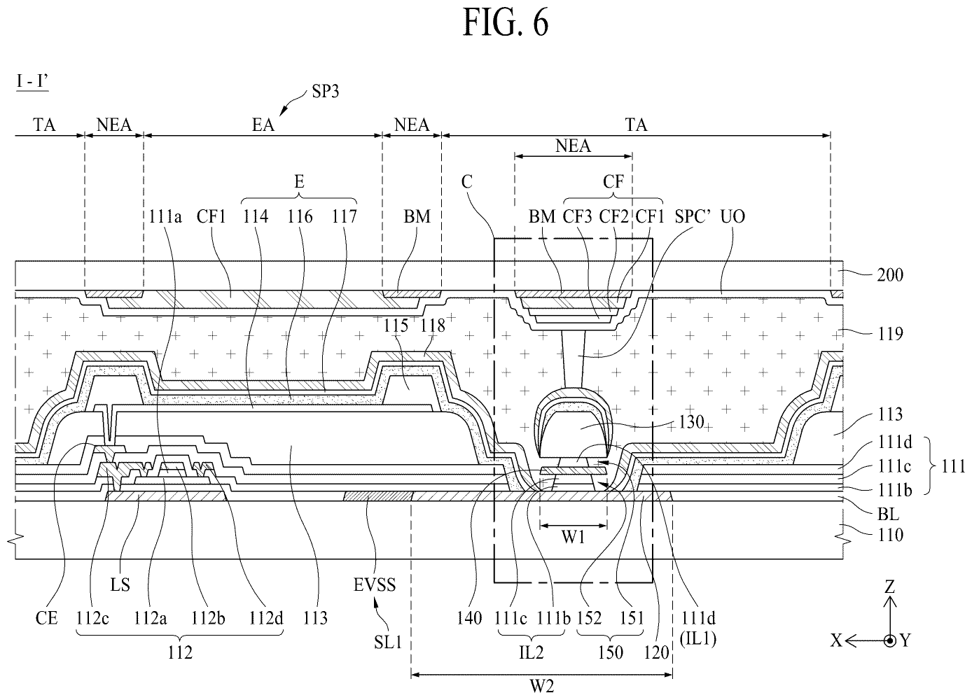

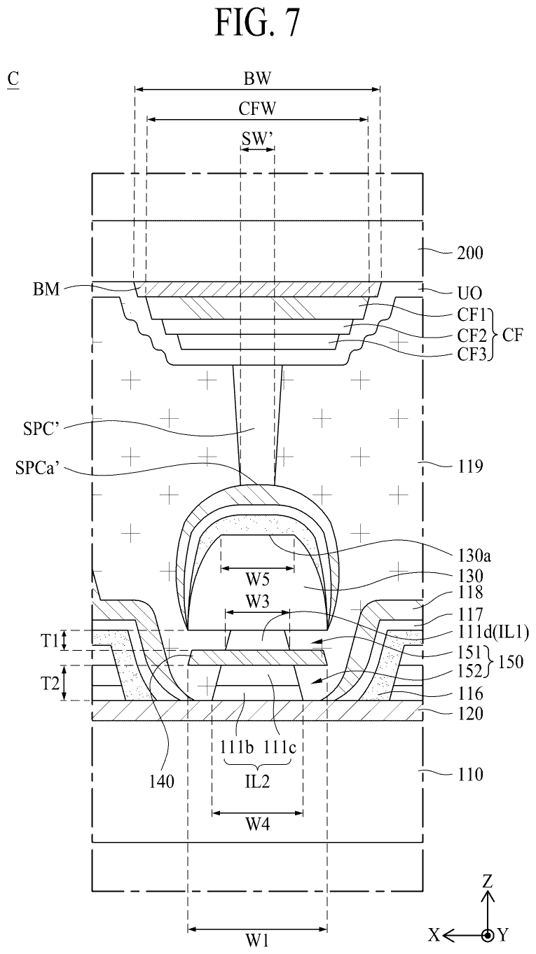

FIG. 6 is a plan view showing a transparent display apparatus according to another embodiment of the present disclosure, and FIG. 7 is a schematic enlargement view of portion C of FIG. 6.

Referring to FIG. 6, the transparent display apparatus 100 according to another embodiment of the present disclosure is the same as the transparent display apparatus according to FIG. 1 described above, except that the pattern structure PS is omitted and a structure of the spacer SPC is changed. Therefore, the same drawing symbols have been assigned to the same configuration, and only the different configurations will be described hereinafter.

In the case of the transparent display apparatus according to FIG. 1, the pattern structure PS and the spacer SPC on the auxiliary line 120 can function as a support for maintaining the cell gap (or interval) between the substrate 110 and the opposing substrate 200 together with the plurality of inorganic films 111, the planarization layer 130, the at least one color filter CF, and the black matrix BM. Therefore, the transparent display apparatus 100 according to one embodiment of the present disclosure can have improved reliability against external impact (or external force) without a separate support. In addition, in the case of a transparent display apparatus 100 according to one embodiment of the present disclosure, the width SW of the spacer SPC is provided to be larger than the width W5 of the pattern structure PS, so that the alignment time can be reduced. In addition, the transparent display apparatus 100 according to one embodiment of the present disclosure can have a structural feature in which the pattern structure PS is covered by the organic light-emitting layer 116, the cathode electrode 117, and the encapsulation layer 118.

In contrast, in the case of the transparent display apparatus according to FIG. 6, the pattern structure PS can be omitted. This is because in the case of the transparent display apparatus according to FIG. 6, a thickness (or a height) of the spacer SPC is changed compared to the transparent display apparatus according to FIG. 5. For example, in the case of the transparent display apparatus according to FIG. 6, the thickness (or the height) of the spacer SPC′ can be provided to be thicker than the spacer SPC of the transparent display apparatus according to FIG. 5. Accordingly, in the case of the transparent display apparatus according to FIG. 6, the pattern structure PS can be omitted, and thus the planarization layer 130 (or the upper surface 130a of the planarization layer 130) on the auxiliary line 120 can be provided to be covered by the organic light-emitting layer 116, the cathode electrode 117, and the encapsulation layer 118. In this case, the upper surface 130a of the planarization layer 130 can be in contact with the organic light-emitting layer 116.

Meanwhile, referring to FIG. 7, the transparent display apparatus 100 according to another embodiment of the present disclosure can be provided with a narrower width SW′ of the spacer SPC′ (or an upper surface SPCa of the spacer SPC′) compared to the transparent display apparatus according to FIG. 1. For example, the transparent display apparatus 100 according to another embodiment of the present disclosure can be provided with a width SW′ of the spacer SPC′ (or the upper surface SPCa of the spacer SPC′) smaller than the width W5 of the planarization layer 130 (or the upper surface 130a of the planarization layer 130).

Therefore, in the transparent display apparatus 100 according to another embodiment of the present disclosure, the width SW′ of the spacer SPC′ (or the upper surface SPCa of the spacer SPC′) is provided to be smaller than the width W5 of the planarization layer 130 (or the upper surface 130a of the planarization layer 130), so that the area occupied by the spacer SPC′ in the transmissive area TA can be minimized or reduced, and thus the reduction in the transmittance (or transparency) of the transmissive area TA can be minimized. This is because if the width of the spacer SPC′ is reduced, the width of at least one color filter CF and the black matrix BM placed over the spacer SPC′ can also be reduced.

In addition, in the transparent display apparatus 100 according to another embodiment of the present disclosure, the width SW′ of the spacer SPC′ (or the upper surface SPCa of the spacer SPC′) is provided to be smaller than the width W5 of the planarization layer 130 (or the upper surface 130a of the planarization layer 130), so that the alignment margin between the opposing substrate 200 and the substrate 110 can be further secured, so that the reduction in alignment time can be maximized, and thus the tact time of the transparent display apparatus can be reduced.

Embodiments of the present disclosure have been described in more detail with reference to the accompanying drawings, but the present disclosure is not necessarily limited to these embodiments and can be implemented in various modifications without departing from the technical ideas of the present disclosure. Accordingly, the embodiments disclosed herein are intended to illustrate and not to limit the technical ideas of the present disclosure, and the scope of the technical ideas of the present disclosure is not limited by these embodiments. Therefore, the embodiments described above are exemplary in all respects and should be understood as non-limiting. The scope of protection of this disclosure shall be construed by the claims, and all technical ideas within the scope of the claims shall be construed to be included within the scope of the claims.

The present disclosure in some aspects provides the plurality of spacer, so that a cell gap between the substrate (the lower substrate) and the opposing substrate (the upper substrate) can be maintained.

Furthermore, the present disclosure in some aspects can include a plurality of undercut portions so that a disconnection of the encapsulation layer can be maximized, thereby blocking crack propagation through the encapsulation layer.

Furthermore, the present disclosure in some aspects is provided such that the encapsulation layer seals the light emitting elements of each of the plurality of subpixels, thereby preventing moisture penetration into the light emitting elements.

Furthermore, the present disclosure in some aspects provides that crack propagation is blocked by a plurality of undercut portions, thereby improving the life of a light-emitting element, and thus enabling the light-emitting element to be driven with low power in terms of its overall lifespan, thereby reducing power consumption.

Furthermore, the present disclosure in some aspects provides that a width of the spacer is smaller than a width of the planarization layer (or island OC), so that the reduction in transmittance (or transparency) of the transmissive area can be minimized.

Furthermore, the present disclosure in some aspects provides that the planarization layer (or island OC) on the auxiliary line is provided to support the upper substrate, so that reliability against external force can be improved.

The effects that can be obtained from the present disclosure are not limited to those mentioned above, and other effects not mentioned will be apparent to one having ordinary skill in the art from the following description.

What is claimed is:

1. A transparent display apparatus comprising:
a substrate having a plurality of pixels, each of at least one of the plurality of pixels having a transmissive area and a plurality of subpixels;
an auxiliary line arranged on the substrate and overlapping the transmissive area;
a planarization layer arranged on the auxiliary line;
a blocking portion arranged between the planarization layer and the auxiliary line;
a plurality of undercut portions partially arranged on an upper side and a lower side of the blocking portion;
an opposing substrate arranged on the planarization layer; and
a plurality of spacers arranged between the planarization layer and the opposing substrate.

2. The transparent display apparatus of claim 1, wherein each of the plurality of subpixels includes a plurality of light-emitting element layers configured to emit light,
wherein the substrate further includes an encapsulation layer covering the plurality of light-emitting element layers, and
wherein the encapsulation layer is disconnected by the plurality of undercut portions.

3. The transparent display apparatus of claim 2, wherein the plurality of undercut portions include a first undercut portion partially disposed between the blocking portion and the planarization layer.

4. The transparent display apparatus of claim 3, wherein the plurality of undercut portions further include a second undercut portion disposed below the first undercut portion and partially disposed between the blocking portion and the auxiliary line.

5. The transparent display apparatus of claim 4, wherein the substrate further comprises:
a first inorganic film disposed adjacent to the first undercut portion and between the blocking portion and the planarization layer; and
a second inorganic film disposed below the first inorganic film and between the blocking portion and the auxiliary line, and
wherein a thickness of the second inorganic film is thicker than a thickness of the first inorganic film.

6. The transparent display apparatus of claim 5, wherein a width of the first inorganic film is narrower than a width of the blocking portion.

7. The transparent display apparatus of claim 5, wherein a width of the second inorganic film is wider than a width of the first inorganic film and is narrower than a width of the blocking portion.

8. The transparent display apparatus of claim 1, wherein a width of the blocking portion is narrower than a width of the auxiliary line.

9. The transparent display apparatus of claim 1, further comprising:
a common power line partially overlapping each of the plurality of sub-pixels,
wherein the auxiliary line extends from the transmissive area toward one of the plurality of sub-pixels and is connected to the common power line.

10. The transparent display apparatus of claim 4, wherein each of the plurality of subpixels comprises:
an overcoat layer disposed on the substrate;
a pixel electrode disposed on the overcoat layer;
an organic light-emitting layer disposed on the pixel electrode; and
a cathode electrode disposed on the organic light-emitting layer,
wherein the cathode electrode is disposed below the encapsulation layer and is in contact with the auxiliary line in the second undercut portion.

11. The transparent display apparatus of claim 10, wherein the organic light-emitting layer is disconnected by the plurality of undercut portions.

12. The transparent display apparatus of claim 10, wherein the opposing substrate further comprises:
a black matrix partially overlapping the planarization layer;
at least one color filter arranged on the black matrix; and
an upper organic film covering the at least one color filter.

13. The transparent display apparatus of claim 12, wherein a width of the at least one color filter is narrower than a width of the black matrix.

14. The transparent display apparatus of claim 12, wherein one of the at least one color filter is arranged to extend to one of the plurality of sub-pixels.

15. The transparent display apparatus of claim 12, wherein the at least one color filter comprises:
a first color filter arranged on the black matrix;
a second color filter arranged on the first color filter; and
a third color filter arranged on the second color filter,
wherein the planarization layer overlaps the first color filter, the second color filter, and the third color filter.

16. The transparent display apparatus of claim 12, further comprising:
a pattern structure arranged on an upper surface of the planarization layer,
wherein the pattern structure is covered by the organic light-emitting layer, the cathode electrode, and the encapsulation layer.

17. The transparent display apparatus of claim 16, wherein each of the plurality of subpixels further includes a bank covering an edge of the pixel electrode, and
wherein the pattern structure is arranged on a same layer as the bank.

18. The transparent display apparatus of claim 16, wherein each of the plurality of spacers is arranged between the encapsulation layer covering the pattern structure and the upper organic film, and
wherein a width of the planarization layer is larger than a width of the pattern structure and is equal to or smaller than a width of at least one of the plurality of spacers.

19. The transparent display apparatus of claim 12, wherein the planarization layer is covered by the organic light-emitting layer, the cathode electrode, and the encapsulation layer.

20. The transparent display apparatus of claim 19, wherein each of the plurality of spacers is arranged between the encapsulation layer covering the planarization layer and the upper organic film, and
wherein a width of each of the plurality of the spacers is smaller than a width of the planarization layer.

21. The transparent display apparatus of claim 2, wherein a portion of the encapsulation layer disposed over the planarization layer is in contact with the plurality of spacers respectively.

22. The transparent display apparatus of claim 10, wherein the planarization layer is formed on a same layer as the overcoat layer and formed as an island shape spaced apart from the overcoat layer.

23. A transparent display apparatus comprising:
a substrate having a plurality of subpixels and at least one transmissive area adjacent to the subpixels;
a planarization layer arranged on the substrate and overlapping the at least one transmissive area;
a blocking portion arranged between the planarization layer and the auxiliary line;
a plurality of undercut portions partially arranged on upper side and lower side of the blocking portion; and
an encapsulation layer covering the plurality of subpixels and extending to the at least one transmissive area,
wherein the encapsulation layer is disconnected by the plurality of undercut portions.
